(19) United States
(12) Patent Application Publication
(10) Pub. No.: US 2013/0286599 A1
(43) Pub. Date: Oct. 31, 2013

(54) PANEL MOUNTING ASSEMBLY

(71) Applicant: HON HAI PRECISION INDUSTRY CO., LTD., New Tapei (TW)

(72) Inventor: CHEN-LU FAN, New Taipei (TW)

(73) Assignee: HON HAI PRECISION INDUSTRY CO., LTD., New Taipei (TW)

(21) Appl. No.: 13/709,206

(22) Filed: Dec. 10, 2012

(30) Foreign Application Priority Data
Apr. 26, 2012 (TW) 101114826

(51) Int. Cl. H05K 7/14

(52) U.S. Cl. CPC H05K 7/1489
USPC 361/726

(57) ABSTRACT

A panel mounting assembly includes a cabinet frame, a panel, and a locking apparatus. The cabinet frame includes a pair of supporting rails. An engaging slot is defined in each of the pair of supporting rails. The panel is attached to the pair of supporting rails. The locking apparatus includes a rotatable latch rotatably attached to the panel, a pair of latch bars movably attached to the panel, and an engaging member protruding from each of the pair of latch bars. The rotatable latch is rotatable between a released position when the rotatable latch is disengaged from the engaging member and each of the pair of latch bars is disengaged from the engaging slot, and a locked position when the rotatable latch is resisted against the engaging member and each of the latch bars is moved away from each other and engaged with the engaging slot.

### BACKGROUND

1. Technical Field

The present disclosure relates to a panel mounting assembly.

2. Description of Related Art

A computer system, such as a blade server system, includes a cabinet frame, a plurality of computer modules mounted in the cabinet frame, and a plurality of panels attached to an outside of the cabinet frame to shield the computer modules. The installation of the plurality of panels usually involves the use of screws, which is inconvenient.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an assembled view of a panel mounting assembly in accordance with an embodiment.

FIG. 2 is an isometric, partially exploded, cutaway view of the panel mounting assembly of FIG. 1, the panel mounting assembly including a panel module and a cabinet frame.

FIG. 3 is an exploded, cutaway view of a panel module of FIG. 2.

FIG. 4 is an assembled, cutaway view of the panel mounting assembly of FIG. 2, showing the panel module in an unlocked state.

FIG. 5 is an assembled view of the panel module of FIG. 3, showing the panel module in an unlocked state.

FIG. 6 is similar to FIG. 4, but shows the panel mounting assembly in a locked state.

FIG. 7 is similar to FIG. 5, but shows the panel module in a locked state.

### DETAILED DESCRIPTION

The disclosure is illustrated by way of example and not by way of limitation. In the figures of the accompanying drawings, like references indicate similar elements. It should be noted that references to “an” or “one” embodiment in this disclosure are not necessarily to the same embodiment, and such references mean at least one.

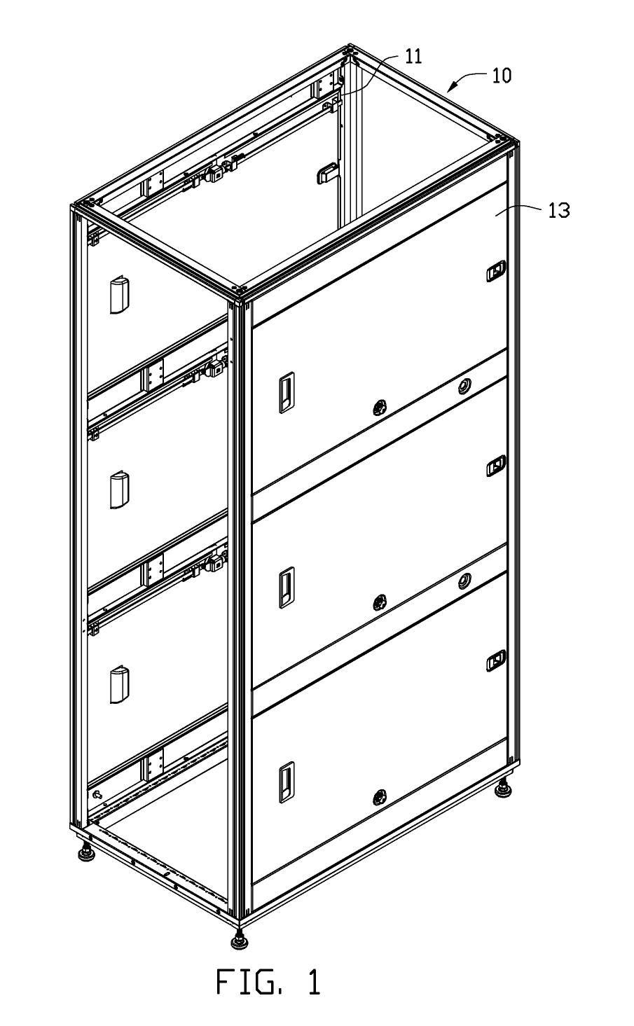

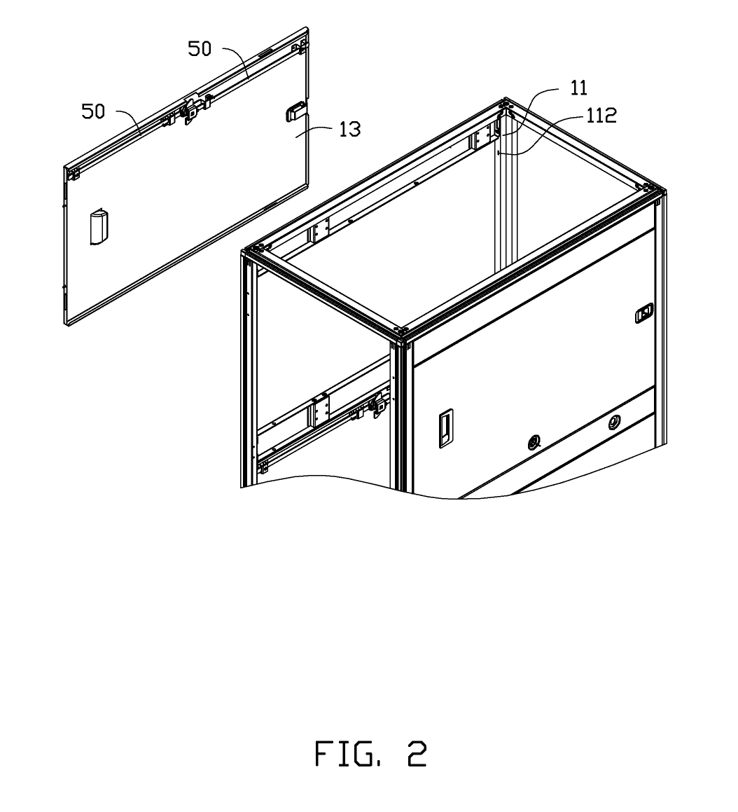

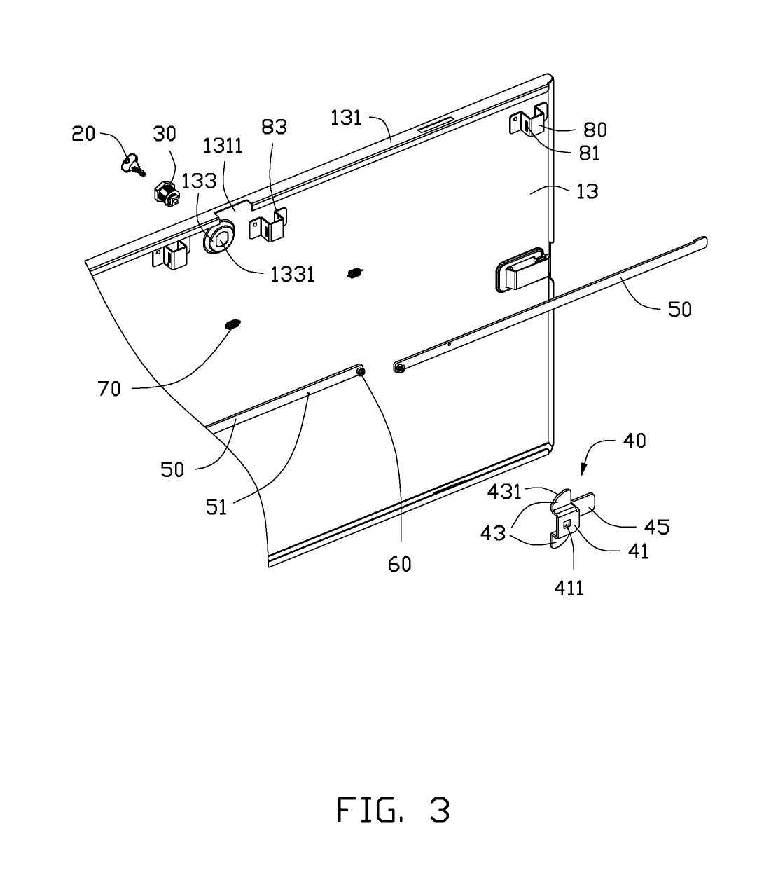

Referring to FIGS. 1 to 3, an embodiment of a panel mounting assembly includes a cabinet frame 10 and a panel 13 adapted to be attached to the cabinet frame 10. The cabinet frame 10 includes two pairs of vertical rails 11 and a plurality of horizontal rails attached to the plurality of vertical rails 11. An engaging slot 112 is defined in each of the two pairs of vertical rails 11. In one embodiment, a panel mounting assembly further comprises a plurality of panels similar to the panel 13 attached to the cabinet frame 10. The cabinet frame 10 can be used to accommodate a plurality of computer blades of a blade server system.

A top flange 131 extends inwardly from an upper edge of the panel 13. A gap 1311 is defined in the top flange 131. A locking apparatus is attached to an inner side of the panel 13. The locking apparatus includes a key 20, a locking body 30, a rotatable latch 40, a pair of latch bars 50, a pair of resilient members 70, and two pairs of holding members 80 securely attached to the panel 13. The two pairs of holding members 80 are located below and adjacent to the top flange 131. A circular mounting portion 133 protrudes inwardly from the panel 13. A mounting hole 1331 is defined in the circular mounting portion 133. A lock aperture (not shown) is defined in a front side of the locking body 30 corresponding to the key 20.

The rotatable latch 40 is integrally formed and has a symmetrical structure. The rotatable latch 40 includes a main piece 41, a pair of driving flanges 43 extending from upper and lower edges of the main piece 41, and a blocking flange 45 extending from a rear edge of the main piece 41. Each of the pair of driving flanges 43 includes an arc-shaped edge 431. The blocking flange 45 may be L-shaped, for example. A locking hole 411 is defined in a central portion of the main piece 41.

Each of the pair of latch bars 50 includes a first end attached to an engaging member 60, and a second end engageable in the engaging slot 112. In one embodiment, the engaging member 60 is a screw secured to the first end and protrudes from each of the pair of latch bars 50. A first clamping hole 51 is defined in each of the pair of latch bars 50. Each of the pair of resilient members 70 is a spring. The first clamping hole 51 is configured to engage with a first end of the spring. A pair of holding slots 81 is defined in each of the two pairs of holding members 80 for holding each pair of latch bars 50. A second clamping hole 83 is defined in one of the pairs of holding members 80 for engaging with a second end of the spring. In one embodiment, a width of each pair of latch members 50 is not greater than a length of each holding slots 81. A width of each pair of holding slots 81 is substantially equal to a thickness of each latch bar 50.

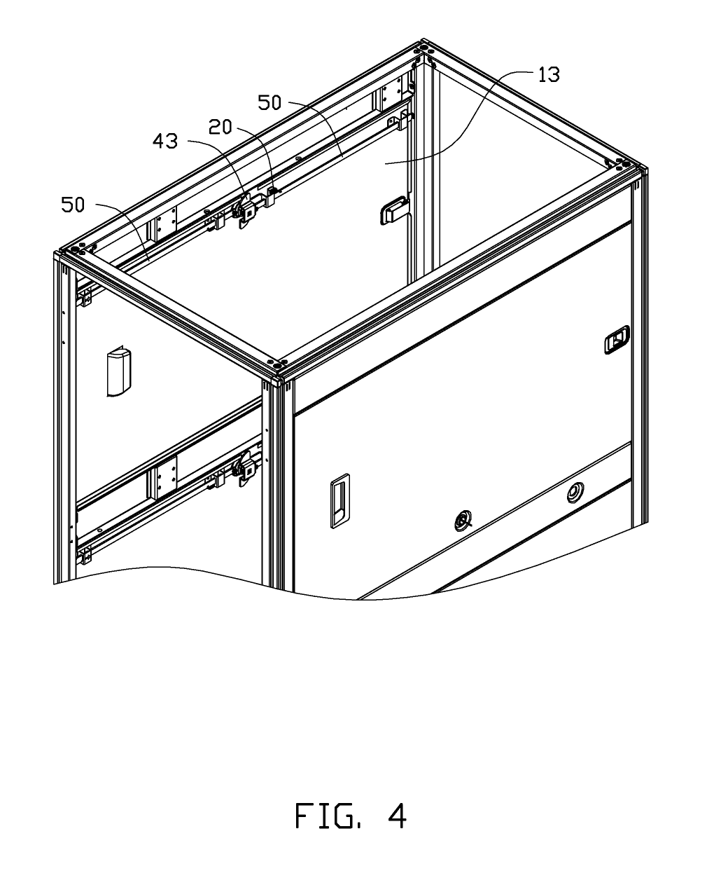

Referring to FIGS. 4 to 7, in assembly, the locking body 30 is mounted in the circular mounting portion 1331. A rear end of the locking body 30 protrudes through the mounting hole 1331 and extends into the locking hole 411. The rotatable latch 40 is securely attached to the rear end of the locking body 30. Each of the pair of latch bars 50 extends through the pair of holding slots 81. The pair of latch bars 50 is held by the two pairs of holding members 80. A first end of each resilient member 70 is engaged with the first clamping hole 51. A second end of each resilient member 70 is engaged with the second clamping hole 83. The locking apparatus is attached to the inner side of the panel 13. The panel 13 is attached to the cabinet frame 10 and located between one pair of vertical rails 11. Each of the pair of latch bars 50 is aligned with the engaging slot 112.

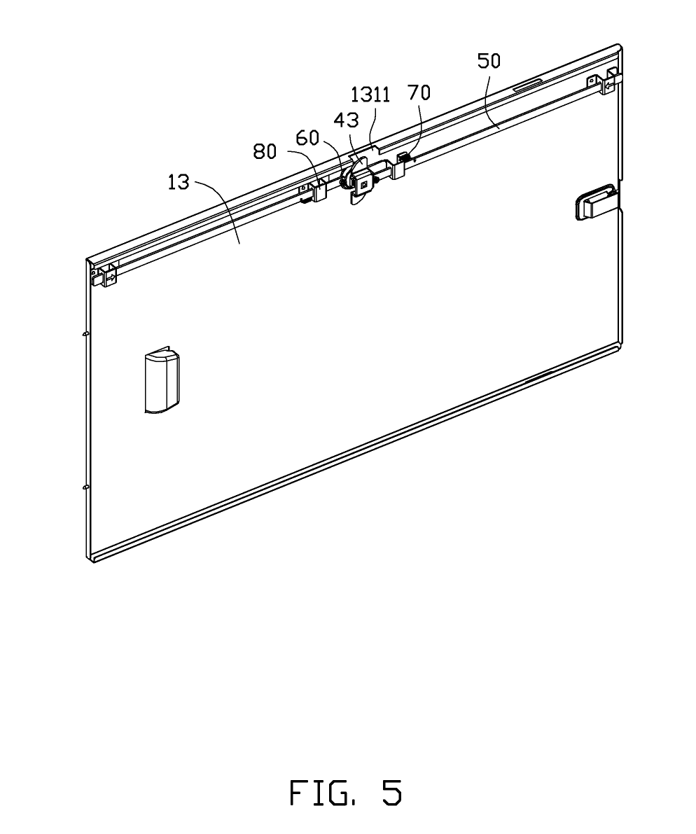

When the rotatable latch 40 is located at a released position (see FIGS. 4-5), the pair of driving flanges 43 is located at upper and lower sides of the main piece 41. The blocking flange 45 is oriented in a horizontal direction. The arc-shaped edge 431 is disengaged from the engaging member 60. The pair of resilient members 70 is in an original state. Each of the pair of latch bars 50 does not protrudes out from the boundary of the panel 13 and is disengaged from the engaging slot 112. Thus, the panel 13 is in an unlocked state.

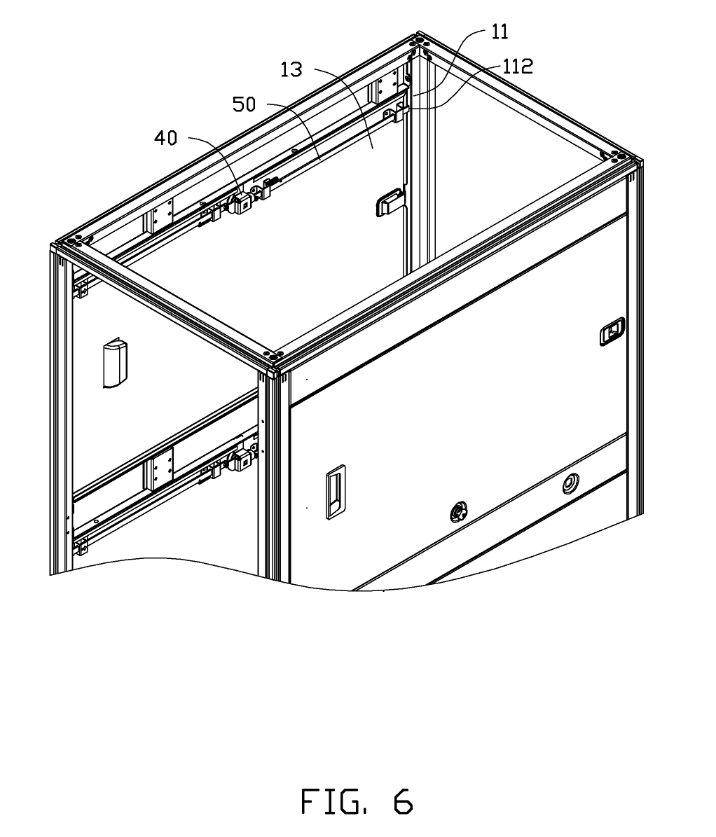

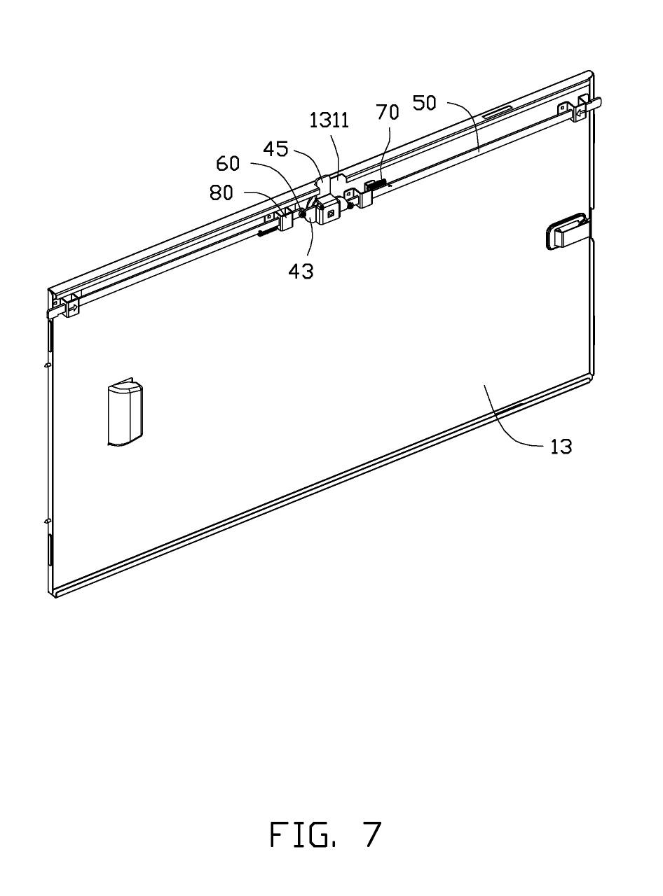

When the rotatable latch 40 is rotated 90 degrees counterclockwise and reaches a locked position (see FIGS. 6-7), the pair of driving flanges 43 is located at left and right sides of the main piece 41. The blocking flange 45 is oriented in a vertical direction. The rotatable latch 40 cannot rotate in the counterclockwise direction when the blocking flange 45 is engaged with a front edge of the gap 1311. The arc-shaped edge 431 is engaged with the engaging member 60. The pair of driving flanges 43 urges the pair of latch bars 50 moving in opposite horizontal directions. Each resilient member 70 is in a stretched state. Each latch bar 50 protrudes out from the boundary of the panel 13 and engages with the engaging slot 112. Thus, the panel 13 is secured to the cabinet frame 10 and in a locked state.

To detach the panel 13, the key 20 is inserted into the locking body 30 and drives the rotatable latch 40 rotating from the locked position to the released position. The pair of resilient members 70 returns to its original state. The pair of latch bars 50 is pulled back by the pair of resilient members 70 and disengaged from the engaging slot 112. Thus, the panel 13 can be detached from the cabinet frame 10.

While the present disclosure has been illustrated by the description in this embodiment, and while the embodiment has been described in considerable detail, it is not intended to restrict or in any way limit the scope of the appended claims to such details. Additional advantages and modifications within the spirit and scope of the present disclosure will readily appear to those skilled in the art. Therefore, the present disclosure is not limited to the specific details and illustrative examples shown and described.

What is claimed is:

1. A panel mounting assembly comprising:
a cabinet frame comprising a pair of supporting rails;
a panel attached to the pair of supporting rails; and
a locking apparatus comprising a rotatable latch rotatably attached to the panel, a pair of latch bars movably attached to the panel, and two engaging members protruding from each of the pair of latch bars, wherein an engaging slot is defined in each of the pair of supporting rails; the rotatable latch is rotatable between a released position and a locked position; the released position is when the rotatable latch is disengaged from the engaging member and each of the pair of latch bars is disengaged from the engaging slot; and the locked position is when the rotatable latch is resisted against the two engaging members and the pair of latch bars is moved away from each other and engaged with the engaging slot.

2. The panel mounting assembly of claim 1, wherein the rotatable latch comprises a main piece, a pair of driving flanges extending from a pair of opposite edges of the main piece, and a blocking flange extending from a rear edge of the main piece; and each of the pair of driving flanges is resisted against the two engaging members in the locked position.

3. The panel mounting assembly of claim 2, wherein each of the pair of opposite edges is substantially perpendicular to the rear edge.

4. The panel mounting assembly of claim 2, wherein a top flange extends from a top edge of the panel, a gap is defined in the top flange, and the blocking flange is resisted against an edge of the gap in the locked position.

5. The panel mounting assembly of claim 2, wherein each of the pair of driving flanges has an arc-shaped edge engaged with each of the two engaging members in the locked position.

6. The panel mounting assembly of claim 5, wherein the rotatable latch is integral and has a symmetrical structure.

7. The panel mounting assembly of claim 1, wherein the locking apparatus further comprises a locking body and a key matched with the locking body, the locking body is attached to the panel and exposed to an outside of the panel, and the rotatable latch is attached to a rear side of the locking body and rotatable by the key.

8. The panel mounting assembly of claim 1, further comprising a pair of holding members attached to the panel, wherein a holding slot is defined in each of the pair of holding members, and each of the pair of latch bars is movable in the holding slot.

9. The panel mounting assembly of claim 8, wherein the locking apparatus further comprises a pair of resilient members, and each of the pair of resilient members is attached to one of the pair of latch bars for urging the pair of latch bars to move close to each other.

10. The panel mounting assembly of claim 9, wherein when the rotatable latch is in the locked position, the pair of latch bars protrudes out from a pair of side edges of the panel to engage with the engaging slot; and when the rotatable latch is in the released position, the pair of latch bars do not protrude out from the pair of side edges.

11. A panel mounting assembly comprising:
a cabinet frame comprising a pair of supporting rails, an engaging slot is defined in each of the pair of supporting rails;
a panel attached to the pair of supporting rails;
a rotatable latch rotatably attached to the panel and rotatable between a released position and a locked position;
a pair of latch bars attached to the panel and movable in opposite directions; and
an engaging member attached to and protruding from a first end of each of the pair of latch bars;
wherein when the rotatable latch is in the released position, the rotatable latch is disengaged from the engaging member, and a second end of each of the pair of latch bars is disengaged from the engaging slot; and when the rotatable latch is in the locked position, the rotatable latch is resisted against the engaging member, and a second end of each of the latch bars is engaged with the engaging slot.

12. The panel mounting assembly of claim 11, wherein the rotatable latch comprises a main piece, a pair of driving flanges extending from a pair of opposite edges of the main piece, and a blocking flange extending from a rear edge of the main piece; and each of the pair of driving flanges is resisted against the engaging members in the locked position.

13. The panel mounting assembly of claim 12, wherein each of the pair of opposite edges is substantially perpendicular to the rear edge.

14. The panel mounting assembly of claim 12, wherein a top flange extends from a top edge of the panel, a gap is defined in the top flange, and the blocking flange is resisted against an edge of the gap in the locked position.

15. The panel mounting assembly of claim 12, wherein each of the pair of driving flanges has an arc-shaped edge engaged with the engaging member in the locked position.

16. The panel mounting assembly of claim 15, wherein the rotatable latch is integrally formed and has a symmetrical structure.

17. The panel mounting assembly of claim 11, further comprising a locking body and a key mated with the locking body, wherein the locking body is attached to the panel and exposed to an outside of the panel, and the rotatable latch is attached to a rear side of the locking body and rotatable by the key.

18. The panel mounting assembly of claim 11, further comprising a pair of holding members attached to the panel for holding each of the pair of latch bars, wherein a pair of holding slots is defined in each of the pair of holding members, and each of the pair of latch bars is movable in the pair of holding slots.

19. The panel mounting assembly of claim 18, further comprising a pair of resilient members, wherein each of the pair of resilient members is attached to one of the pair of latch bars and one of the pair of holding members for urging the pair of latch bars to move close to each other.

20. The panel mounting assembly of claim 19, wherein when the rotatable latch is in the locked position, the pair of latch bars protrudes out from a pair of side edges of the panel to engage with the engaging slot; and when the rotatable latch is in the released position, the pair of latch bars do not protrude out from the pair of side edges.
